(19) United States
(12) Patent Application Publication
(10) Pub. No.: US 2006/0006514 A1
(43) Pub. Date: Jan. 12, 2006

(54) Interconnecting integrated circuits using MEMS

(76) Inventors: Manish Sharma, Sunnyvale, CA (US); Robert G. Walmsley, Palo Alto, CA (US)

Correspondence Address: HEWLETT-PACKARD COMPANY;Intellectual Property Administration, P.O. Box 272400, Fort Collins, CO, 80527-2400, US

(21) Appl. No.: 10/886,970

(22) Filed: Jul. 7, 2004

(51) Int. Cl. H01L 23/06

(52) U.S. Cl. 257/684

(57) ABSTRACT

A semiconductor device comprises a plurality of integrated circuits and at least one MEMS device interconnecting the integrated circuits for signal transmission between the circuits.

### BACKGROUND

Conventionally, integrated circuit chips have generally communicated with one another through external wiring on a printed circuit board. The external wiring typically includes metal conductors that make connections to the integrated circuit at one end and the printed circuit board at the other end. Multiple integrated circuits, each in contact with the printed circuit board, can then be connected through the printed circuit board. This kind of interconnection is referred to as direct (or conductive) coupling.

Metal conductors have transmission speed limits that cannot be exceeded. A signal to be transmitted through a conductor (e.g., from one chip to another chip) can generally be regarded (e.g., via Fourier or z-transform decomposition) as a series of pulses of oscillating currents. At high transmission speeds, the oscillating currents in a conducting line may begin to emit radio frequencies, thereby effectively causing the conducting line to act as a transmission line. Radio frequencies are generally undesirable because they may interfere with and/or corrupt data stored in the chips. Thus, metal conductors typically can only transmit signals up to a certain predetermined speed. However, a higher signal transmission speed is a desirable quality because it generally improves the overall performance of a device.

One technique to overcome the transmission speed limit is to transmit signals using some other form of coupling. For example, a capacitor may be formed between two chips to allow signals to be transmitted between them via capacitive coupling.

In one known technique for forming a capacitor between two chips, the two chips are aligned (e.g., the signal pads of the two chips are aligned) to form the two plates of the capacitor having a dielectric material (e.g., air, silicon dioxide, etc.) between the plates. Changes in the electrical potential of the signal pad of one chip causes corresponding changes in the electrical potential of the signal pad of the other chip. Signal communication between the two chips is effectuated by detecting the changing electrical potential of their respective signal pads. Suitable drivers and sensing circuits known in the art may be implemented to enable the signal communication.

Typically, because of resistance within the circuit elements, so-called capacitive coupling is not purely capacitive (C), but also includes a resistive (R) component. In many cases, the coupling behaves like a RC circuit acting as a high pass filter. Accordingly, in many capacitive coupling implementations, higher frequencies are transmitted better than low frequencies. Indeed, capacitive coupling will typically not transmit the DC (or zero frequency) component of a signal.

Mathematically, a graph of gain as a function of frequency will have a characteristic “knee” shape, with the curve asymptotically approaching 1 (i.e., unity gain, or perfect transmission) for higher frequencies, and steeply decreasing toward 0 (i.e., zero gain, or no transmission) for lower frequencies. The location of the knee of the curve is roughly proportional to a characteristic frequency of 1/RC.

This means that the lowest frequency that can reliably be transmitted (i.e., with an acceptably high gain) using capacitive coupling is an inverse function of capacitance. Thus, for the capacitor formed by aligning the signal pads of two chips to function reliably, the signal pads must be precisely positioned at a pre-calculated spacing distance. Thus, current methods require precise alignment of chips to achieve reliable maximum frequency.

Thus, a market exists for techniques to interconnect chips that are not limited to the maximum transmission speeds of conventional external metal conductors, and also do not require precise alignments as in the conventional methods of capacitive coupling.

### SUMMARY

A semiconductor device comprises a plurality of integrated circuits and at least one MEMS device interconnecting at least two of the integrated circuits for signal transmission between the circuits.

A method for interconnecting integrated circuits comprises interconnecting a plurality of integrated circuits by at least one MEMS device and utilizing the at least one MEMS device to receive a signal from at least one of the integrated circuits and transmit the signal to another of the integrated circuits.

Other embodiments and implementations are also described below.

### BRIEF DESCRIPTION OF THE FIGURES

FIG. 1A illustrates a side view of an exemplary interconnection of two chips using at least one MEMS device.

FIG. 1B illustrates an exemplary top view of the exemplary interconnection of FIG. 1A.

FIG. 2 illustrates another exemplary interconnection of two chips using at least one MEMS device.

FIG. 3 illustrates a side view of an exemplary interconnection of two or more chips using at least one MEMS device.

FIG. 4 illustrates a top view of an exemplary interconnection of two or more chips using at least one MEMS device.

FIG. 5 illustrates a top view of another exemplary interconnection of two or more chips using at least one MEMS device.

FIG. 6 illustrates an exemplary process for interconnecting at least two chips with at least one MEMS device.

### DETAILED DESCRIPTION

### I. OVERVIEW

Exemplary improved techniques for interconnecting integrated circuits are described herein.

Section II describes exemplary MEMS technologies for interconnecting integrated circuits.

Section III describes an exemplary MEMS device for interconnecting two integrated circuits via capacitive coupling.

Section IV describes another exemplary MEMS device for interconnecting two integrated circuits via conductive coupling.

Section V describes a modification of the exemplary MEMS device of Section IV, for interconnecting two integrated circuits via capacitive coupling.

Section VI describes a modification of the exemplary MEMS device of Section V, for interconnecting two integrated circuits via capacitive coupling.

Section VII describes an exemplary MEMS frame for interconnecting more than two integrated circuits.

Section VIII describes using a MEMS device for interconnecting two integrated circuits using inductive coupling.

Section IX describes signal conditioning by the selective application of different types of coupling.

Section X describes an exemplary process for interconnecting two or more integrated circuits via a MEMS device.

### II. EXEMPLARY MEMS TECHNOLOGIES FOR INTERCONNECTING INTEGRATED CIRCUITS

Micro-electro-mechanical systems (MEMS) devices generally refer to movable (e.g., positionable, flexible, etc.) micro-mechanical structures built on silicon wafers (or other substrates) using integrated circuit processing techniques. The micro-mechanical elements may also be combined with micro-electronic elements such as those commonly found in semiconductor devices. Micro-fabrication technologies for forming MEMS devices include known integrated circuit fabrication techniques that selectively etch away parts of a silicon wafer or add new structural layers to form desired mechanical or electromechanical devices. Such fabrication processes include, without limitation, those used to fabricate CMOS, bipolar, BICMOS, and many other types of semiconductor devices. Other types of micro-machining processes (e.g., via lasers) may also be used for fabrication.

MEMS devices often exhibit electronic properties. Such electronic properties can arise in a wholly mechanical fashion, for example, by configuring hydraulic or other forms of mechanical gates to create a computing device. Alternatively, the electronic properties can arise from constructing electrical components (such as inductors, capacitors, and inductors) from mechanical structures (e.g., a parallel plate capacitor). As yet another alternative, the electronic properties can arise from including micro-electronic elements such as those comprising semiconductor (and other electronic) devices. Finally, the electronic properties can arise in a hybrid fashion, from both the micro-mechanical and/or micro-electronic elements.

Hybrid MEMS devices can also enable the development of smarter products by using the computational capabilities of electronics to control movable micro-mechanical parts. For example, micro-sensors may be implemented in a MEMS device to gather information from the environment through measuring mechanical, thermal, biological, chemical, optical, and/or magnetic phenomena. The gathered information then can be processed by the electronics within the MEMS device. The electronics may also direct any micro-mechanical elements in a MEMS device to move, position, regulate, pump, filter, and/or perform other tasks whether or not based on information gathered by the micro-mechanical elements. These tasks, in turn, can be used to construct complex computing systems that are useable in controlling the MEMS device and/or facilitating communication between the integrated circuits interconnected thereby.

### III. AN EXEMPLARY MEMS DEVICE FOR INTERCONNECTING INTEGRATED CIRCUITS USING CAPACITIVE COUPLING

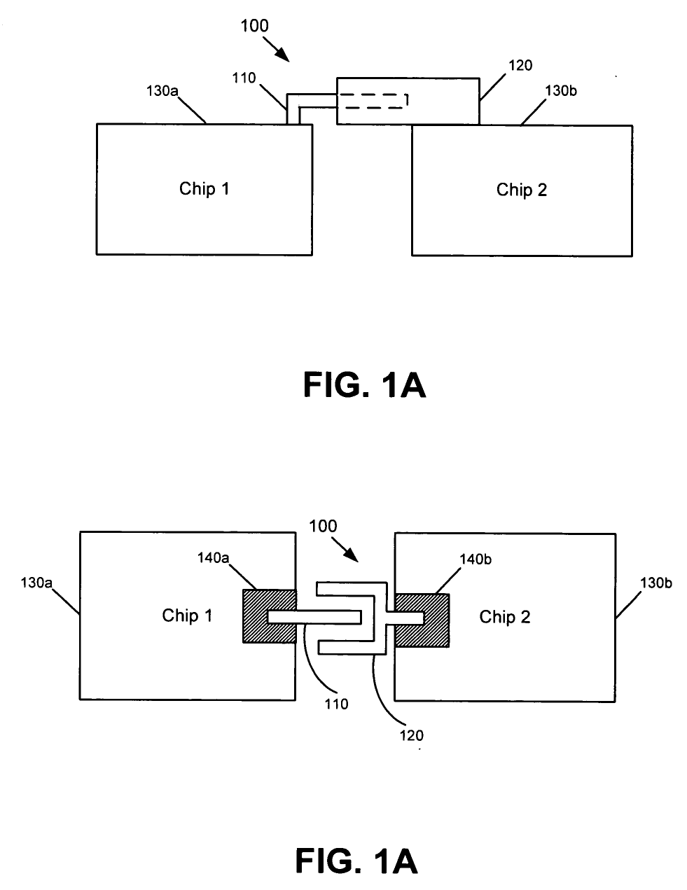

FIGS. 1A and 1B illustrate an exemplary interconnection of two integrated circuits 130a and 130b using an exemplary MEMS device 100 to achieve capacitive coupling. FIG. 1A illustrates a side view, and FIG. 1B illustrates a top view, of the exemplary interconnection.

In FIGS. 1A and 1B, first chip 130a and second chip 130b are interconnected by the MEMS device 100. The MEMS device includes a finger 110 coupled to chip 130a via a signal pad 140a and a finger 120 coupled to chip 130b via a signal pad 140b. The fingers 110 and 120 can be made of any conducting, semiconducting or non-conducting material depending on design choice.

For example, if the desired form of coupling is capacitive, the fingers would be made of a material suitable for forming a capacitor, and the region between the fingers would contain an appropriate dielectric (e.g., air, paper, plastic, film mica, glass, ceramic, vacuum, etc.).

More specifically, in this exemplary implementation, fingers 110 and 120 are adjustable (e.g., by any positioning mechanism) and interleaved, but do not make electrical contact with each other. In effect, a capacitor is formed by the two fingers 110 and 120 for transmitting signals between the two chips 130a and 130b via capacitive coupling.

The spacing of the chips in this exemplary MEMS device can be precisely controlled (either statically or dynamically), thus eliminating the uncertainty associated with externally positioning chips 130a and 130b with respect to each other, as in non-MEMS capacitive coupling.

In an exemplary implementation, each finger 110 or 120 can be controlled by one or more positioning mechanisms (not shown) to dynamically adjust its position relative to the other finger. For example, a feedback circuit can be implemented to achieve a predetermined capacitance between the fingers 110 and 120 by maintaining (e.g., adjusting as necessary) a fixed distance between the two fingers 110 and 120. Further, the feedback circuit can also detect any closing of the gap (or even the occurrence of electrical contact) between the fingers 110 and 120, and adjust one or more of the fingers accordingly. Design and fabrication of feedback circuits are well known in the art. As just one example, the feedback circuit could operate by measuring and monitoring the capacitance, which is a direct function of the gap size. Or, one or more MEMS sensors could be deployed to directly measure the relative positions of the fingers. Such feedback circuits can be manufactured in the same or separate process sequence for manufacturing the fingers 110 and 120.

The desired motion of the fingers can be implemented using readily available MEMS positioning devices (including, without limitation, gears, rack-and-pinion assemblies, translation stages, micro manipulator arrays, piezoelectric translators, and actuators), which may be implemented and/or controlled using mechanical (e.g., whether linkage-based, hydraulic, or rotary) and/or electrical (e.g., motor driven) micro-assemblies. Such MEMS positioning devices are well known in the literature, and need not be described in greater detail herein.

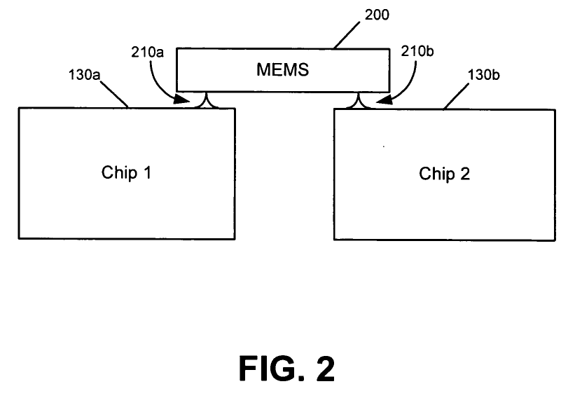

The physical configurations (e.g., geometry, shape, thickness, aspect ratio, etc., of the fingers 110 and 120) illustrated in FIGS. 1A and 1B are merely exemplary. A person skilled in the art will recognize that other physical configurations are also possible to use one or more MEMS devices to interconnect one or more integrated circuits. Other exemplary implementations are illustrated in FIGS. 2-5 to be described below.

### IV. ANOTHER EXEMPLARY MEMS DEVICE FOR INTERCONNECTING TWO INTEGRATED CIRCUITS USING CONDUCTIVE COUPLING

FIG. 2 illustrates another exemplary interconnection of two integrated circuits by at least one MEMS device 200 using conductive coupling.

In FIG. 2, first chip 130a and second chip 130b are interconnected by the MEMS device 200, which is coupled to the chips 130a and 130b by one or more cantilevers 210a and 210b. The cantilevers 210a and 210b may also be considered part of the MEMS device 200. In an exemplary implementation, the cantilevers 210a and 210b electrically contact the chips 130a and 130b via respective signal pads 140a and 140b (see FIG. 1B) at one end of the cantilever, and electrically contact the MEMS device 200 at the other end of the cantilever. The cantilevers 210a and 210b can be made of any conducting material and may also be stressed or bent to a desired shape (such as the exemplary shape shown in FIG. 2) according to design choice.

The use of cantilevers as described above is merely illustrative. A person skilled in the art will recognize that other physical structures and/or materials may be implemented. For example, one or more conducting fingers (or any other elongated structures) may be used instead of the cantilevers 210a and 210b.

In an exemplary implementation, the MEMS device 200 may include conductors for transferring signals between the chips 130a and 130b. Because the length of the conducting wires in the MEMS device 200 is relatively short compared to most conducting wires being used to interconnect chips on a printed circuit board, signals transmitted via the MEMS device 200 can travel at a relatively higher speed than allowable using conventional wiring techniques.

The physical configurations (e.g., geometry, shape, thickness, aspect ratio, etc., of the MEMS device 200 and cantilevers 210a and 210b) illustrated in FIG. 2 are merely exemplary. A person skilled in the art will recognize that other physical configurations are also possible in accordance with design choice.

### V. ANOTHER EXEMPLARY MEMS DEVICE FOR INTERCONNECTING TWO INTEGRATED CIRCUITS USING CAPACITIVE COUPLING

In the foregoing implementation, the cantilevers 210a and 210b made electrical contact with the chips 130a and 130b, and the current flow through MEMS device 200 occurred through conductors.

In a modified version of the foregoing exemplary implementation, the cantilevers 210a and 210b may not make electrical contact with the chips 130a and 130b. Instead, the cantilevers 210a and 210b may form a pair of capacitors with the chips 130a and 130b, respectively. For example, the cantilevers 210a and 210b may be separated from the chips' respective signal pads 140a and 140b by a layer of dielectric material (not shown). In this exemplary implementation, signals from chip 130a are transmitted to the MEMS device 200 via the capacitor formed by chip 130a and the first cantilever 210a. The received signals are then transmitted by the MEMS device 200 to chip 2 130b via the capacitor formed by the second cantilever 210b and chip 2 130b. In this implementation, the cantilevers 210a and 210b may comprise any conducting, semiconducting, or non-conducting material suitable for forming capacitors.

In this exemplary implementation, the current again flows through the MEMS device 200 via conductors.

### VI. ANOTHER EXEMPLARY MEMS DEVICE FOR INTERCONNECTING TWO INTEGRATED CIRCUITS USING CAPACITIVE COUPLING

In yet another modification of the foregoing, the capacitive coupling can be moved to within the MEMS device 200, via incorporation of a suitable capacitor therein (not shown). In this exemplary implementation, signals from chip 130a are received by the MEMS device 200 via direct contact (i.e., conductive coupling) with cantilever 210a. These signals are then transmitted by the capacitor within the MEMS device 200 to chip 130b via direct contact of the cantilever 210b.

Thus, instead of two capacitors (at the cantilevers), the capacitor is located within the MEMS device.

As yet another alternative, capacitors could be located at one of the cantilevers, while the current flowed within the MEMS device via conductors, and the other cantilever remained conductively coupled to the MEMS device. For example, this might be appropriate when it is desired to isolate one of the chips (the capacitively coupled one) from low frequency signals.

In general, then, the specific choices regarding where to deploy conductive and/or capacitive coupling are a matter of design choice.

Techniques for the design and fabrication of MEMS devices comprising wiring and/or capacitor(s) are well known in the art. Such MEMS devices can be manufactured in the same or separate process sequence for manufacturing the cantilevers 210a and 210b in accordance with the requirements of a particular implementation.

### VII. EXEMPLARY MEMS STRUCTURES FOR INTERCONNECTING MORE THAN TWO INTEGRATED CIRCUITS

A. Multiple Chips via a Single MEMS Device

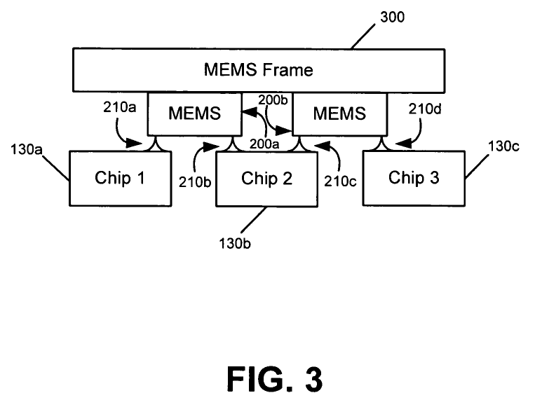

FIG. 3 illustrates a side view of an exemplary interconnection of multiple integrated circuits using a MEMS device.

In FIG. 3, chips 1 and 2 (130a and 130b) are interconnected by MEMS device 200a via cantilevers 210a and 210b. Similarly, chips 2 and 3 (130b and 130c) are interconnected by MEMS device 200b via cantilevers 210b and 210c. In addition, the two MEMS devices are interconnected by a MEMS frame 300.

Longer range signal transmission (as opposed to directly among adjacent chips) may be achieved via the MEMS frame 300. For example, in order to transmit a signal from chip 1 130a to chip 3 130c, the signal from chip 1 130a may first go to MEMS 200a then to the MEMS frame 300 then to MEMS 200b then to chip 3 130c.

In an exemplary implementation, the MEMS frame 300 may include conducting wires for transferring signals between the chips 1, 2, and 3 (130a, 130b, and 130c). Because the length of the conductors in the MEMS frame 300 is relatively short compared to conducting wires being used to interconnect chips on a printed circuit board, signals transmitted via the MEMS frame 300 can travel at a relatively higher speed than allowable in conventional wiring techniques.

The MEMS frame 300 may even provide additional interconnection capabilities for connecting other integrated circuits (not shown) depending on design choice.

In another exemplary implementation, the MEMS frame 300 may include one or more capacitors for transferring signals via capacitive coupling.

Design and fabrication of the MEMS frame 300 comprising conductors, capacitor(s), and/or other electronic elements, are well known in the art. Such MEMS can be manufactured in the same or separate process sequence for manufacturing the cantilevers 210a-210c and/or MEMS devices 200a-200b in accordance with the requirements of a particular implementation.

For example, multiple MEMS devices, such as the MEMS devices 200a and 200b, may be manufactured on a substrate (e.g., a semiconductor wafer) using micro-machining technologies known in the art. In this implementation, after the MEMS devices have been formed, the substrate may be divided into blocks where each block comprises one or more MEMS devices electrically contacting each other through the divided substrate. In this example, each divided substrate may be considered a MEMS frame 300.

In another example, one or more MEMS devices may be assembled onto a circuit board (e.g., a PCB), and interconnected by conducting wires, optical fibers, and/or other interconnection mechanisms. In this example, the circuit board may be considered a MEMS frame 300.

The physical configurations (e.g., geometry, shape, thickness, aspect ratio, etc., and interconnection implementations described above regarding the MEMS frame 300, MEMS 200a-200b and cantilevers 210a-210c) illustrated in FIG. 3 are merely exemplary. A person skilled in the art will recognize that other physical configurations and interconnection techniques are also possible to use one or more MEMS devices to interconnect one or more chips.

B. Multiple Chips via Multiple MEMS Devices

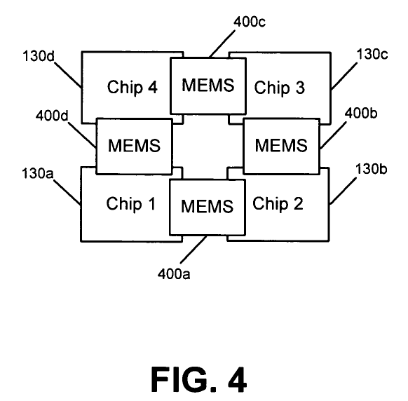

FIG. 4 illustrates a top view of an exemplary configuration of multiple MEMS frames interconnecting multiple integrated circuits. More specifically, integrated circuits 1-4 (130a-130d) are interconnected by four MEMS devices (400a-400d).

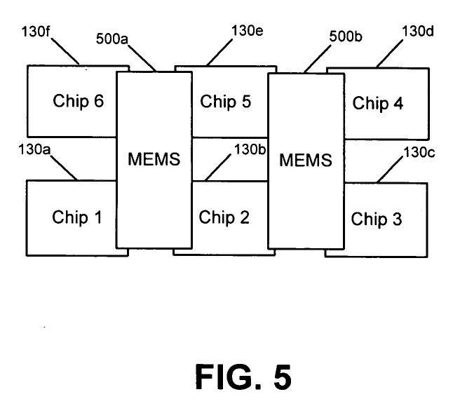

FIG. 5 illustrates a top view of yet another exemplary configuration of MEMS frames to interconnect multiple integrated circuits. In FIG. 5, integrated circuits 1-6 (130a-130f) are interconnected by two MEMS devices (500a-500b).

### VIII. AN EXEMPLARY MEMS DEVICE FOR INTERCONNECTING INTEGRATED CIRCUITS USING INDUCTIVE COUPLING

In the foregoing exemplary embodiments, the current flows through the chip-MEMS interconnections, and/or through the MEMS device(s), occurred through conductive and/or capacitive coupling. Still other types of coupling could also be used, depending on design choice. For example, if a capacitor were replaced by an inductor, the coupling would be inductive.

### IX. SIGNAL CONDITIONING BY SELECTIVE APPLICATION OF DIFFERENT TYPES OF COUPLING

Whereas conductive coupling is frequency-independent, and capacitive coupling generally favors higher frequencies, inductive coupling is generally known to favor lower frequencies. Thus, conductive coupling provides no filtering, capacitive coupling provides high pass filtering, and inductive coupling provides low pass filtering. Accordingly, selective application of different types of coupling in different location within the overall system allows the system designed to selectively effect signal conditioning.

### X. AN EXEMPLARY PROCESS FOR INTERCONNECTING INTEGRATED CIRCUITS WITH MEMS

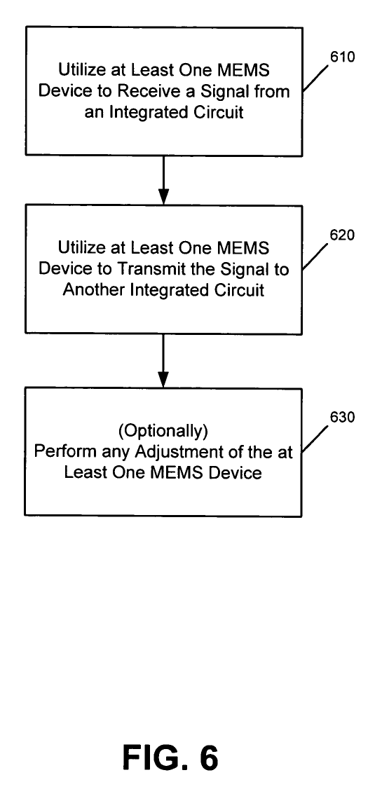

FIG. 6 illustrates an exemplary process for interconnecting integrated circuits with one or more MEMS devices.

At step 610, at least one MEMS device is utilized to receive a signal from a first integrated circuit.

At step 620, at least one MEMS device (which may or may not be the same MEMS device as in step 610) is utilized to transmit the signal to a second integrated circuit.

At step 630, optionally, any adjustment of the MEMS devices positioned at steps 610 and 620 is performed.

The process illustrated above is merely exemplary. Those skilled in the art will appreciate that other steps may be used in accordance with the requirements of a particular implementation.

### XI. CONCLUSION

The types of structures that can be created with MEMS are virtually limitless. Examples of such structures, as well as techniques for manufacturing MEMS devices, are both well known in the art, as well as undergoing continuous development. Accordingly, there are virtually limitless ways to design and implement interconnection circuitry in a MEMS device, and the examples described herein should be regarded as merely illustrative. The inventions should therefore not be limited to the particular embodiments discussed above, but rather are defined by the claims.

Furthermore, some of the claims may include alphanumeric identifiers to distinguish the elements and/or recite elements in a particular sequence. Such identifiers or sequence are merely provided for convenience in reading, and should not necessarily be construed as requiring or implying a particular order of steps, or a particular sequential relationship among the claim elements.

What is claimed is:

1. An electronic device, comprising:
a plurality of integrated circuits; and
at least one MEMS device interconnecting at least two of integrated circuits for signal transmission between said circuits.

2. The device of claim 1, wherein said integrated circuits include a semiconductor device.

3. The device of claim 1, wherein said MEMS device includes mechanical fingers.

4. The device of claim 3, further comprising at least one positioning mechanism configured to adjust the relative positioning of said mechanical fingers.

5. The device of claim 4, further comprising at least one feedback circuit to implement said positioning.

6. The device of claim 1, wherein at least a portion of said signal transmission occurs via conductive coupling.

7. The device of claim 1, wherein at least a portion of said signal transmission occurs via capacitive coupling.

8. The device of claim 1, wherein at least a portion of said signal transmission occurs via inductive coupling.

9. The device of claim 1, wherein at least a portion of said signal transmission occurs via coupling at a juncture of said MEMS device and at least one of said integrated circuits.

10. The device of claim 1, wherein at least a portion of said signal transmission occurs via coupling within said MEMS device.

11. The device of claim 1, wherein said MEMS device includes a capacitor.

12. The device of claim 1, further comprising an elongated element for interconnecting at least one of said integrated circuits to said MEMS device.

13. The device of claim 1, wherein said elongated element includes a cantilever.

14. The device of claim 13, wherein said cantilever makes electrical contact with at least one of said integrated circuits.

15. The device of claim 13, wherein said cantilever is positioned on a dielectric layer above at least one of said integrated circuits.

16. The device of claim 1, wherein said MEMS is positioned on a signal pad of at least one of said two integrated circuits.

17. The device of claim 1, including a plurality of MEMS devices interconnecting said plurality of integrated circuits, and further comprising a MEMS frame interconnecting at least two of said MEMS devices.

18. The device of claim 1, wherein said signal transmission occurs via at least two different coupling types implemented at different locations in said MEMS device.

19. The device of claim 1, wherein said signal transmission occurs via at least one coupling mechanism selected for its signal conditioning characteristics.

20. A method for interconnecting integrated circuits, comprising:
interconnecting a plurality of integrated circuits by at least one MEMS device, where said interconnecting includes:
utilizing said at least one MEMS device to receive a signal from at least one of said integrated circuits; and
utilizing said at least one MEMS device to transmit said signal to another of said integrated circuits.

21. The method of claim 20, wherein said MEMS device includes movable mechanical elements.

22. The method of claim 21, further comprising adjusting said elements by at least one feedback circuit.

23. The method of claim 20, wherein said at least one of said signal reception and said signal transmission occurs via capacitive coupling.

24. The method of claim 20, wherein said at least one of said signal reception and said signal transmission occurs via inductive coupling.

25. The method of claim 20, wherein at least a portion of said interconnecting occurs via coupling at a juncture of said MEMS device and at least one of said integrated circuits.

26. The method of claim 20, wherein at least a portion of said interconnecting occurs via coupling within said MEMS device.

27. The method of claim 20, wherein said interconnecting occurs via at least two different coupling types implemented at different locations.

28. The method of claim 20, wherein said interconnecting occurs via at least one coupling mechanism selected for its signal conditioning characteristics.

29. An apparatus for interconnecting integrated circuits, comprising:
means for interconnecting a plurality of integrated circuits by at least one MEMS device, where said means for interconnecting includes:
means for utilizing said at least one MEMS device to receive a signal from at least one of said integrated circuits; and
means for utilizing said at least one MEMS device to transmit said signal to another of said integrated circuits.

30. The apparatus of claim 29, further comprising means for adjusting the relative positioning of a mechanical finger.

31. The apparatus of claim 29, wherein at least a portion of said signal receiving and transmission occurs via capacitive coupling.

32. The apparatus of claim 29, wherein at least a portion of said signal receiving and transmission occurs via inductive coupling.

33. The apparatus of claim 29, wherein at least a portion of said signal receiving and transmission occurs via coupling at a juncture of said MEMS device and at least one of said integrated circuits.

34. The apparatus of claim 29, wherein said signal transmission occurs via at least one coupling mechanism selected for its signal conditioning characteristics.
